(19) United States
(12) Patent Application Publication
(10) Pub. No.: US 2026/0304907 A1
(43) Pub. Date: Oct. 1, 2026

(54) MONOLITHIC MICROWAVE INTEGRATED CIRCUIT

(71) Applicant: Qorvo US, Inc., Greensboro, NC (US)

(72) Inventors: Yongjie Cui, Plano, TX (US); Shuoqi Chen, Plano, TX (US)

(21) Appl. No.: 19/093,491

(22) Filed: Mar. 28, 2025

(51) Int. Cl. H10D 80/20; H01L 21/02; H01L 21/311; H10D 30/01; H10D 30/47; H10D 62/85; H10D 64/01; H10D 64/27; H10D 86/00; H10D 86/80

(52) U.S. Cl. CPC H10D 80/215; H10D 30/015; H10D 30/471; H10D 62/8503; H10D 64/021; H10D 64/027; H10D 64/411; H10D 80/251; H10D 86/201; H10D 86/80; H10P 14/6336; H10P 14/6339; H10P 14/69433; H10P 50/283

(57) ABSTRACT

Disclosed is a method for fabricating monolithic microwave integrated circuits (MMICs) including forming high-voltage-type gallium nitride (GaN) high electron mobility transistors (HEMTs) with gate lengths between 10 nm and 100 nm. In some embodiments, gate lengths are between 10 nm and 50 nm. In some embodiments the HEMTs are gallium nitride transistors. Dielectric layers are deposited across the entire wafer to create metal-insulator-metal (MIM) capacitors in non-transistor regions. The dielectrics surrounding the gates are selectively removed without excessive overetching, leveraging the high-voltage-gate structure to reduce parasitic capacitances. This process enables efficient integration of HEMTs with passive components on a single wafer, enabling high-frequency performance for applications such as 5G and 6G communication systems.

### GOVERNMENT SUPPORT

This Invention was made with Government support under Agreement No. N00164-19-9-0001, awarded by NSWC Crane Division. The Government has certain rights in the Invention.

### FIELD OF THE DISCLOSURE

The present disclosure relates to methods for fabricating mobility transistors (high electron mobility transistors, HEMTs) integrated into monolithic microwave integrated circuits (MMICs) with reduced parasitic capacitance through high-voltage-type gate structures and selective dielectric removal.

### BACKGROUND

With 5G and emerging 6G applications, gallium nitride (GaN) high electron mobility transistors (HEMTs) are being developed for W and higher frequency bands. This requires gate length to be scaled down to <100 nm along with n+GaN ohmic regrowth for source and drain contacts. As with the gate length down-scaling, gate parasite capacitor reduction is also needed to improve FT and Fmax for high-frequency and high-gain operations. The gate parasite capacitor reduction is usually accomplished by using a thin dielectric passivation layer after gate formation. Although such discrete GaN devices have demonstrated high-frequency operation, GaN devices are conventionally integrated with monolithic microwave integrated circuits (MMICs) and are fabricated on the same wafer, where dielectric layers are deposited for metal-insulator-metal (MIM) capacitors to meet the needs of MMICs. These dielectric layers, usually deposited by plasma-enhanced chemical vapor deposition and/or atomic layer deposition after gate formation, cover the entire wafer surface, including GaN HEMT device areas. To achieve high-frequency performance, these dielectric layer areas around gate-to-drain and gate-to-source need to be removed and only a thin passivation layer is allowed around the gate area. This is the reason why a T-gate process usually shows a Y shape gate and is preferred over a high-voltage (HV) gate process for high-frequency GaN HEMT fabrication since it is relatively efficient to remove dielectric layers around the gate area through a dry etching process. Although a Y-shaped T-gate facilitates the removal of the dielectric layer around the gate, the T-gate process for a <90 nm gate is very challenging due to the limitation of the photo process, and the dry etch process also experiences the difficulties when the device source-to-drain spacing is further scaled down into <1 μm. At the same time, the HV-type gate process demonstrates its ability to scale the gate length further to 50 nm or less. However, due to the T-shaped gate design, the dry etch of the dielectric under the gate requires significant overetching to completely remove the material. This process may be infeasible without damaging the passivation on the GaN surface. Disclosed is an integration process to address these issues.

### SUMMARY

Disclosed is a technology integration approach that provides an effective process flow to fabricate gallium nitride (GaN)-based monolithic microwave integrated circuits (MMICs) for high-frequency and high-gain performance by utilizing the high-voltage (HV) gate-like process for GaN high electron mobility transistor (HEMT) gate scaling down to 50 nm or less. Meanwhile, the disclosed process minimizes the dielectric presence in gate-to-source and gate-to-drain areas during gate creation. The disclosed approach has been successfully applied to N-polar GaN MMIC technology development. Furthermore, it is not limited to N-polar GaN MMIC technologies but can be applied to the on-going advanced D-/G-band GaN-based MMIC technology for 5G and 6G applications.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a first front side process flow diagram for fabricating a monolithic microwave integrated circuit (MMIC) in accordance with the present disclosure.

FIG. 2 is a second front side process flow diagram for fabricating the MMIC started by the first front side process of FIG. 1.

FIG. 3 is a third front side process flow diagram for fabricating the MMIC continued from the second front side process of FIG. 2.

FIG. 4 is a continuation of the third front side process flow diagram from FIG. 3.

FIG. 5 is a continuation of the third front side process flow diagram from FIG. 4.

FIG. 6 is a diagram showing a completed front side fabricated from the first, second, and third front side processes according to the present disclosure.

FIG. 7 is a diagram illustrating a completed monolithic microwave integrated circuit (MMIC) device fabricated in accordance with the present disclosure.

FIG. 8 is a detailed process flow chart for silicon nitride (SiN) passivation after mesa etch.

FIG. 9 is a line drawing of a topside view of a pre-matched MMIC device fabricated with the MMIC integration process of the present disclosure.

FIG. 10 is a block diagram of a wireless communication device in which the pre-matched MMIC device may be employed.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

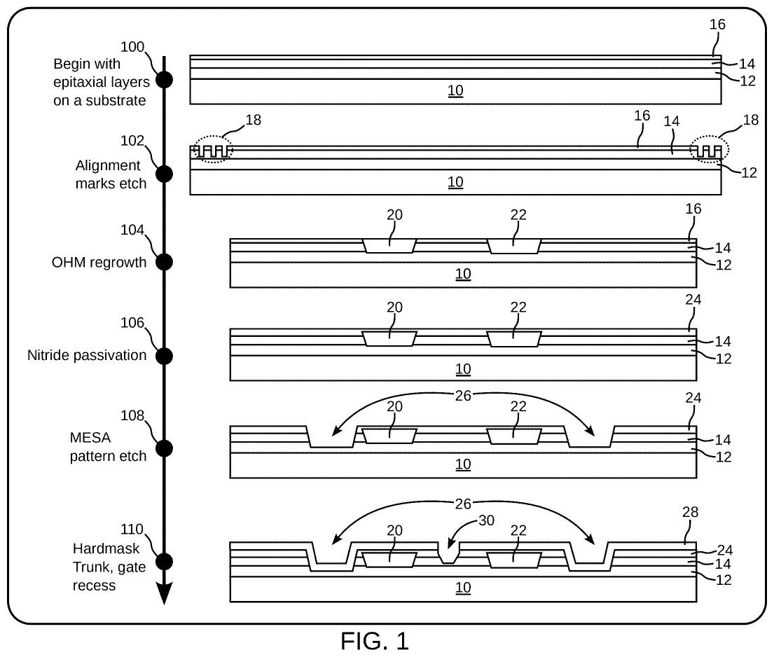

FIG. 1 is a first front side process flow diagram for fabricating a monolithic microwave integrated circuit (MMIC) in accordance with the present disclosure. The process begins with providing a substrate 10 having a buffer layer 12, epitaxial layers 14, and a passivation layer 16 (step 100). In this exemplary embodiment, the substate 10 is made of silicon carbide (SiC), the buffer 12 is a gallium nitride (GaN) buffer, the epitaxial layers are GaN and aluminum gallium nitride (AlGaN) for high electron mobility transistor (HEMT) structure, and the passivation layer 16 is silicon nitride (SiN). Next, alignment marks 18 are etched through the passivation layer 16 and into the epitaxial layers with depth optimized for the process requirement (step 102). Next OHM regrowth creates a source 20 and a drain 22 (step 104). A nitride passivation layer is then formed over the source 20, the drain 22, and passivation layer 16 (step 106). In an exemplary embodiment, the nitride passivation layer is fabricated with silicon nitride that is in the range of 8 nanometers (nm) thick. This passivation layer combines with passivation layer 16 to form layer 24. A mesa pattern etch is then performed to create mesa pattern recesses 26 (step 108) for isolation. A silicon oxide hardmask layer 28 is formed before a trunk and gate recess 30 is formed between the source 20 and the drain 22 (step 110).

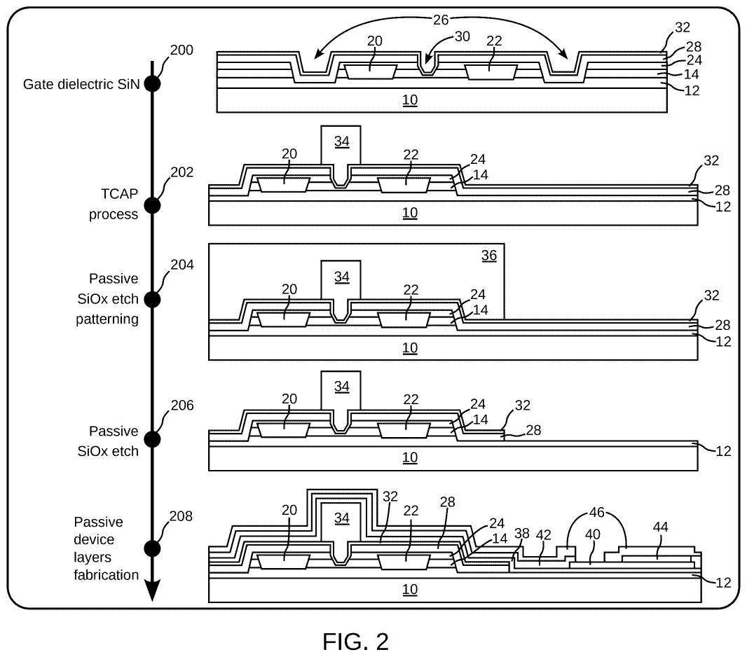

FIG. 2 is a second front side process flow diagram for fabricating the MMIC started by the first front side process of FIG. 1. The second front side process begins with forming a gate dielectric layer 32 (step 200). In this embodiment, the gate dielectric layer 32 is formed using high-quality SiN. Next, a gate electrode 34 is formed at the location of the trunk and gate recess 30 (step 202). In this exemplary embodiment, a T-shaped cap (TCAP) process is used to form the gate electrode 34. A photoresist pattern 36 is formed over the source 20, the gate electrode 34, and the drain 22 using passive silicon oxide (SiOₓ) etch patterning (step 204). Next, a passive SiOₓ etch is performed to remove portions of the gate dielectric layer 32 and the hardmask layer 28 to prepare an area for passive device fabrication (step 206). Passive device layers are then fabricated (step 208). The fabrication process involves a series of depositions, patterning, and etching sub-steps. In this exemplary embodiment, a first nitride N0 layer 38 is first deposited, patterned and then etched, followed by tantalum nitride (TaN) patterning and deposition. This is succeeded by a first metal M0 layer 40 patterning and deposition, and then the second nitride N1 layer 42 deposition, patterning, and etching, along with patterning and deposition of a metal-insulator metal (MIM) capacitor 44. Finally, the process includes a third nitride N2 layer 46 deposition and etching.

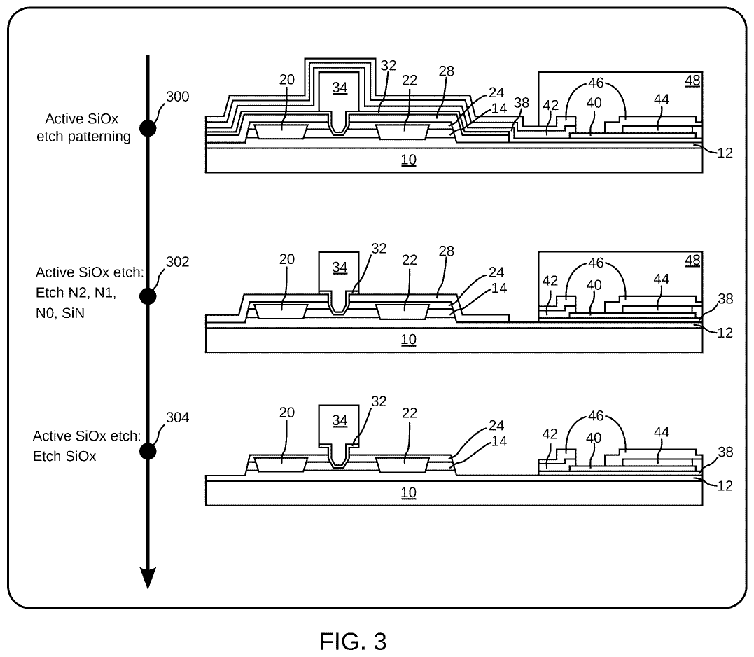

FIG. 3 is a third front side process flow diagram for fabricating the MMIC continued from the second front side process of FIG. 2. Active SiOₓ etch patterning adds a photoresist layer 48 (step 300). Next, an active SiOₓ etch process etches away unprotected portions of the third nitride N2 layer 46, the second nitride N1 layer 42, the first nitride N0 layer 38, the gate dielectric layer 32, and SiOₓ layer 28 (step 302). The photoresist layer 48 is then removed by solvent clean (step 304).

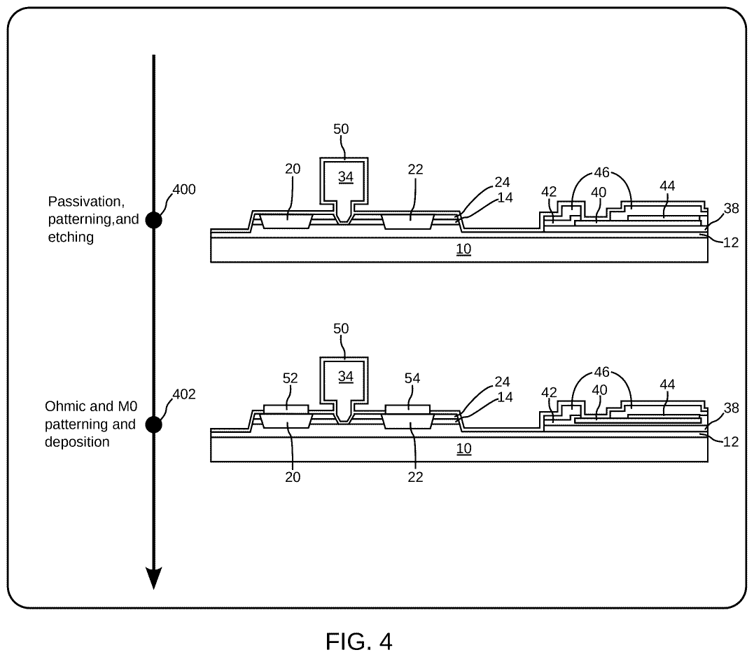

FIG. 4 is a continuation of the third front side process flow diagram from FIG. 3. A passivation layer 50 is deposited along with patterning and etching in preparation for further processing (step 400). Ohmic and first metal M0 layer 40 patterning and deposition are conducted to fabricate a source electrode 52 and a drain electrode 54 (step 402).

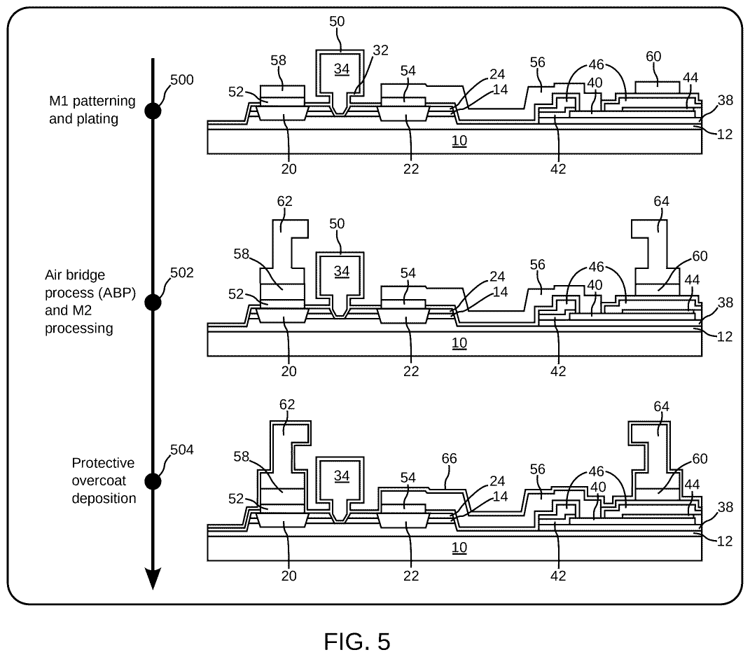

FIG. 5 is a continuation of the third front side process flow diagram from FIG. 4. Second metal layer M1 patterning and plating is processed to fabricate a conductive interconnect 56 between the drain electrode 54 and the first metal M0 layer 40 that is coupled to the MIM capacitor 44 (step 500). In addition, a source pedestal 58 is formed over the source electrode 52 and a passive pedestal 60 is formed over the MIM capacitor 44 during second metal layer M1 patterning and plating. Next, during air bridge post (ABP) and third metal layer M2 processing (step 502), third metal layer M2 structure 62 is formed over the source pedestal 58 and third metal layer M2 structure 64 is formed over the passive pedestal 60. A protective overcoat (PO) 66 is formed during PO deposition (step 504). In FIG. 5 at step 504, the passivation layer 50 on gate electrode 34 merges into PO 66.

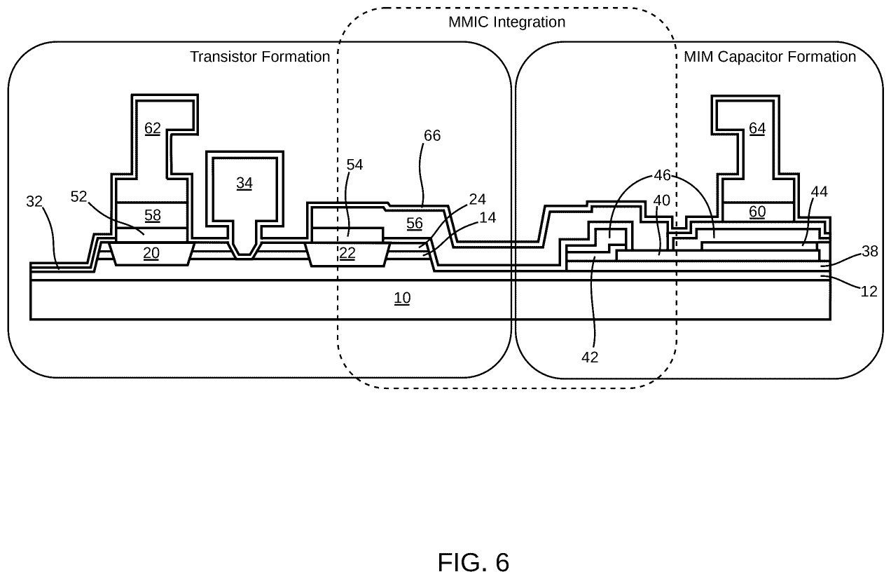

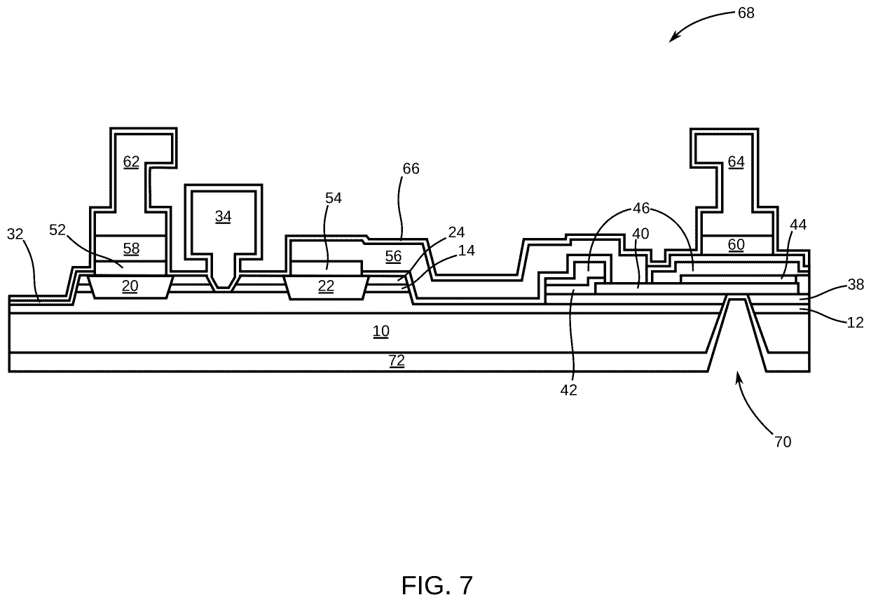

The disclosed integration process is divided into three modules as shown in FIG. 6 and FIG. 7 for N-polar gallium nitride (GaN) deep recess technology:
1. GaN transistor formation.
2. metal-insulator-metal (MIM) capacitor formation.
3. Monolithic microwave integrated circuit (MMIC) integration.

FIG. 6 is a diagram showing a completed front side fabricated from the first, second, and third front side processes according to the present disclosure.

The first front side process is associated with transistor formation, the second front side process is associated with passive MIM capacitor and resistor formation, and the third front side process is associated with MMIC integration.

FIG. 7 is a diagram showing a complete MMIC device 68. A via 70 extends through the substrate 10 to make conductive contact with the first metal M0 layer 40. A back side metal 72 is plated on an opposed side of the substrate 10 and inside of the via 70.

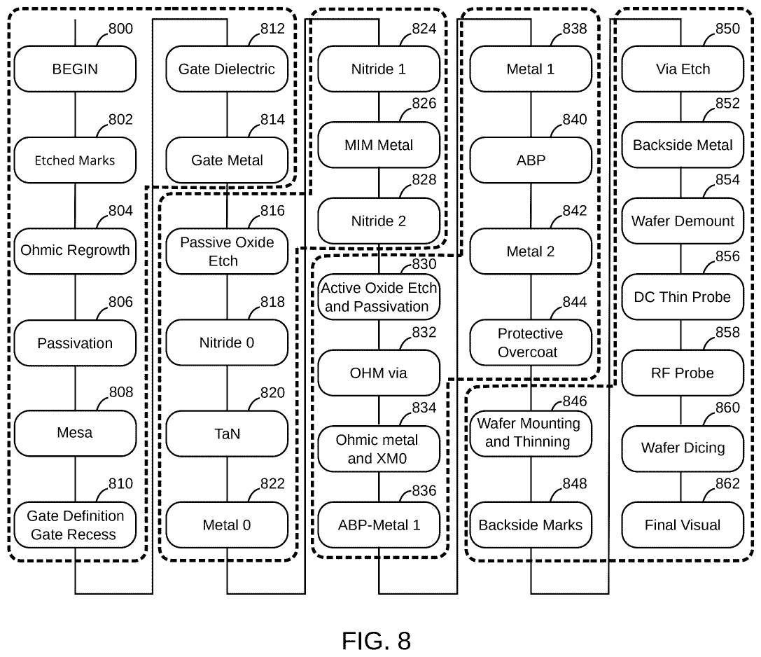

FIG. 8 is a detailed process flow chart with silicon nitride (SiN) passivation after mesa etch. Beginning the fabrication sequence, a first step is initiating processing on a suitable semiconductor substrate, typically silicon carbide (SiC), with GaN HEMT epitaxial structures, and possessing a specified crystal orientation and resistivity, followed by initial cleaning procedures to remove surface contaminants prior to subsequent steps (step 800). Following this preparation, another step is the creation of alignment marks on the substrate using photolithography and etching techniques; these marks serve as fiducial points for precise layer-to-layer alignment in subsequent patterning processes to ensure accurate feature placement (step 802).

Subsequently, a next step involves establishing low-resistance contacts to the semiconductor substrate for improved current injection/extraction through an ohmic regrowth process (step 804). This typically entails selective etching of the existing surface layer followed by n+GaN regrowth. Building upon this contact formation, another step is depositing a SiN layer, controlling deposition parameters to achieve desired film stoichiometry and thickness for passivation (step 806). To provide electrical isolation, yet another step is defining the perimeter of the active device area and providing electrical isolation via anisotropic etching in a mesa process, utilizing etch chemistry offering high selectivity between semiconductor material and masking layers (step 808).

Continuing with device definition, a next step is defining the gate region of the transistor through photolithography and etching, including a recess etched into the semiconductor material beneath where the gate will be formed to optimize threshold voltage characteristics (step 810). The etch process employs a selective etchant for precise depth control. Following this, another step is depositing another high-quality SiN layer functioning as a gate dielectric; its thickness and quality are critical for device performance influencing capacitance and breakdown voltage, necessitating precise deposition parameter control (step 812). A next step then involves patterning via photolithography and depositing a metal layer, typically a high-work function metal such as chromium/gold or ruthenium/gold, to form the gate electrode using sputtering, evaporation, or atomic layer deposition (ALD) and their combination (step 814).

Further processing includes another step of selectively removing a passive oxide layer, utilizing etchant chemistry chosen for selective removal without damaging underlying layers (step 816). Subsequently, a next step is depositing a first nitride layer N0 that is typically made of SiN, which may serve as passivation, a diffusion barrier, or a stressor in subsequent processing (step 818). Following this, another step involves depositing a thin film of TaN for resistors (step 820). A next step is then patterning and depositing a first metallization layer (Metal 0) using titanium- and gold-based metal stack (step 822).

To continue building the layered structure, another step involves depositing a second nitride layer N1 that is typically made of SiN as capacitor dielectric (step 824). A next step is then patterning and depositing a MIM metal layer, which serves as a capacitor plate (step 826). Following this, another step involves depositing a third nitride layer N2 that is typically made of SiN for serving as a capacitor dielectric (step 828). A next step is selectively etching an active oxide layer followed by deposition of a passivation layer to protect the device from environmental factors and improve reliability, typically using silicon dioxide or SiN (step 830).

Preparing for higher-level interconnects, another step involves forming vias through insulating layer on HEMT source and drain pads to connect metal 0 to subsequent metal layers for ohmic contact formation, utilizing photolithography, etching, and potentially a dielectric liner deposition (step 832). A next step is depositing an ohmic metal stack and possibly an extended metal layer (XM0) layer to improve the ohmic contact resistance, similar to element 804 but at a later stage in the process flow (step 834). Continuing with metallization, another step involves patterning a first air bridge post (ABP) structure (step 836). A next step is then depositing and patterning a second metal layer, metal 1, performing a similar function to metal 0 and connecting HEMT to passive devices (step 838).

Continuing frontside processing, another step involves implementing a second ABP step; the specific details depend on the target application (step 840). A next step is depositing and patterning a third metal layer, metal 2, continuing to build interconnects (step 842). To protect the wafer during subsequent handling and testing, another step involves applying a protective overcoat layer, typically dielectric layer, such as silicon nitride, silicon oxide, and others (step 844). Following this, a next step is mounting the wafer onto a carrier for ease of handling and then thinning it using mechanical grinding or chemical etching techniques to reduce device substrate thickness and improve thermal performance (step 846).

Finalizing preparation for back side process, another step involves creating alignment marks on the backside of the wafer used for subsequent backside process processes (step 848). A next step is then etching vias through insulating layers on the backside to connect to the front side metal, often using deep reactive-ion etching (DRIE), for example (step 850). Following this, another step involves depositing a metal layer on the backside of the wafer forming interconnects for ground connections (step 852). A next step is removing the wafer from the mounting carrier after backside processing is complete (step 854). Concluding fabrication and testing, another step is performing electrical testing using direct current (DC) probing techniques to verify functionality and performance characteristics of the fabricated devices (step 856). Radio frequency (RF) characterization follows as a next step, measuring parameters such as S-parameters, power, and noise figure (step 858). Finally, another step is dicing the wafer into individual die using a precision saw or laser cutting system (step 860), followed by a final visual inspection of the diced die to identify any defects or damage before packaging (step 862).

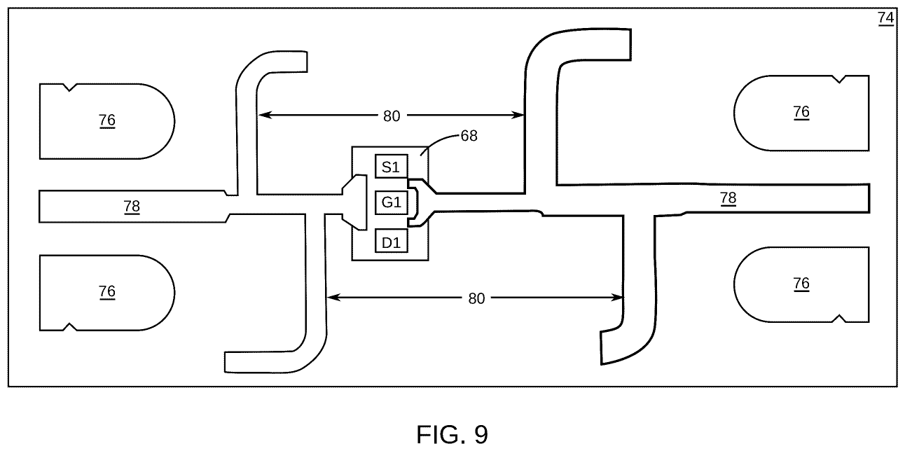

FIG. 9 is a line drawing of a topside view of a pre-matched MMIC device 74 fabricated with the MMIC integration process of the present disclosure. The pre-matched MMIC device 74 includes ground pads 76, microstrip transmission lines 78, and opened-stubs 80 that are configured to provide impedance matching. The MMIC device 68 fabricated by the process steps of the present disclosure is centrally located between and coupled to the microstrip transmission lines 78. The source (S1), gate (G1), and drain (D1) are depicted for the MMIC active device 68. The pre-matched MMIC 74 is configured to operate at frequencies substantially around 75 GHz.

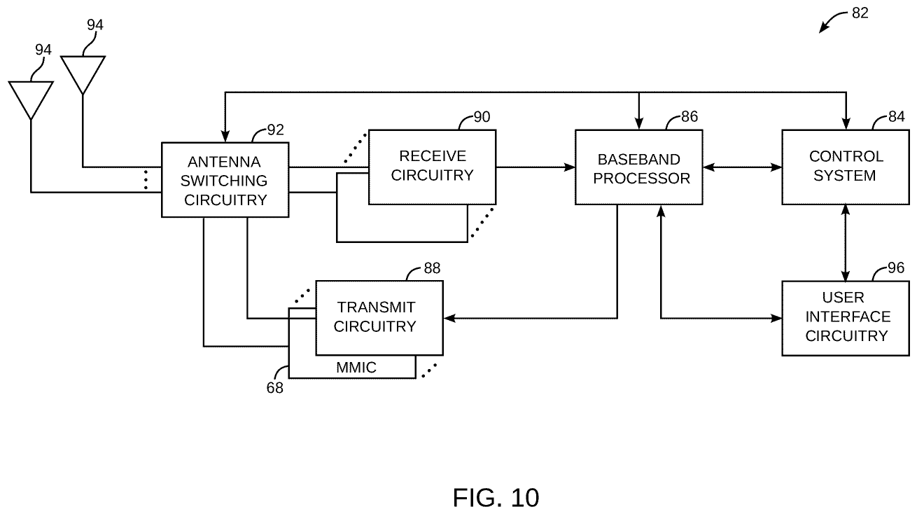

With reference to FIG. 10, the concepts described above may be implemented in various types of wireless communication devices or user elements 82, such as mobile terminals, smart watches, tablets, computers, navigation devices, access points, and the like that support wireless communications, such as cellular, wireless local area network (WLAN), Bluetooth, and near-field communications. The user elements 82 will generally include a control system 84, a baseband processor 86, transmit circuitry 88 that includes the MMIC device 68 (FIG. 7), receive circuitry 90, antenna switching circuitry 92, multiple antennas 94, and user interface circuitry 96.

The receive circuitry 90 receives radio frequency signals via the antennas 94 and through the antenna switching circuitry 92 from one or more basestations. A low-noise amplifier and a filter (not shown) cooperate to amplify and remove broadband interference from the received signal for processing. Downconversion and digitization circuitry (not shown) then downconvert the filtered, received signal to an intermediate or baseband frequency signal, which is then digitized into one or more digital streams.

The baseband processor 86 processes the digitized received signal to extract the information or data bits conveyed in the received signal. This processing typically comprises demodulation, decoding, and error correction operations. The baseband processor 86 is generally implemented in one or more digital signal processors and application-specific integrated circuits.

For transmission, the baseband processor 86 receives digitized data, which may represent voice, data, or control information, from the control system 84, which it encodes for transmission. The encoded data are output to the transmit circuitry 88, where they are used by a modulator (not shown) to modulate a carrier signal that is at a desired transmit frequency or frequencies. A power amplifier such as MMIC device 68 amplifies the modulated carrier signal to a level appropriate for transmission and delivers the modulated carrier signal to the antennas 94 through the antenna switching circuitry 92. The antennas 94 and the transmit circuitry 88 and receive circuitry 90 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method for fabricating a monolithic microwave integrated circuit (MMIC) comprising:
forming high electron mobility transistors (HEMTs) having high voltage (HV)-type gates with gate lengths of between 10 nm and 100 nm;
depositing dielectric layers over the entire wafer surface, including over the HEMTs, for forming metal-insulator-metal (MIM) capacitors in non-HEMT regions;
selectively removing portions of the deposited dielectric layers from around the gates of the HEMTs to minimize parasitic capacitances without requiring substantial overetching due to the HV-type gate structure; and
integrating the HEMTs with passive components on the same wafer via metal interconnections.

2. The method of claim 1 wherein the HEMTs are gallium nitride transistors.

3. The method of claim 1 wherein depositing dielectric layers comprises using plasma-enhanced chemical vapor deposition (PECVD) and/or atomic layer deposition (ALD).

4. The method of claim 1 further comprising depositing a silicon nitride (SiN) passivation layer during transistor formation.

5. The method of claim 1 wherein forming HV-type gates includes utilizing an additional spacer process with silicon oxide (SiOₓ) or SiN to adjust gate length critical dimension (CD).

6. The method of claim 1 further comprising recessing a GaN cap layer during transistor formation to stop on an aluminum gallium nitride (AlGaN) barrier layer.

7. The method of claim 1 further comprising protecting passive devices with photoresist during removal of dielectric layers from HEMT regions.

8. The method of claim 1 wherein removing deposited dielectric layers comprises wet etching to expose underlying gate structures.

9. The method of claim 1 further comprising depositing a thin passivation layer over the MMIC after removing the dielectric layers from the HEMTs.

10. The method of claim 1 wherein the gate lengths are between 10 nm and 50 nm.

11. A gallium nitride (GaN) monolithic microwave integrated circuit (MMIC), comprising:
high electron mobility transistors (HEMTs) formed with high-voltage (HV)-type gates scaled to between 10 nanometers (nm) and 100 nm;
passive components integrally formed on the same wafer as the HEMTs, wherein dielectric layers for metal-insulator-metal (MIM) capacitors are selectively removed from regions adjacent to gate electrodes of the HEMTs after fabrication of the MIM capacitors; and
interconnection layers electrically coupling the HEMTs and the MIM capacitors, thereby minimizing parasitic capacitances around the gates for enhanced high-frequency performance.

12. The MMIC of claim 11 further comprising a thin dielectric passivation layer selectively disposed only in regions adjacent to gate electrodes post-MIM capacitor formation.

13. The MMIC of claim 11 wherein the HV-type gates are formed using an additional spacer process with silicon oxide (SiOₓ) or silicon nitride (SiN) to adjust critical dimensions.

14. The MMIC of claim 11 further comprising recessed gate structures where a GaN cap layer is etched to stop on an aluminum gallium nitride (AlGaN) barrier layer.

15. The MMIC of claim 11 wherein the dielectric layers for MIM capacitors are removed from HEMT regions using a wet etch process after protecting passive devices with photoresist.

16. The MMIC of claim 11 further comprising interconnection layers formed via air bridges and multiple metal layers (M0, M1, M2) for high-frequency signal routing.

17. The MMIC of claim 11 wherein the passivation layer deposited post-HEMT fabrication comprises high-density SiN formed by atomic layer deposition (ALD).

18. The MMIC of claim 11 wherein the passive components are metal-insulator-metal (MIM) capacitors.

19. The MMIC of claim 11 wherein the HEMTs are gallium nitride transistors.

20. The MMIC of claim 11 wherein the gate lengths are between 10 nm and 50 nm.

21. A wireless communication device comprising:
receive circuitry configured to receive radio frequency (RF) signals;
a baseband processor configured to process a digitized version of the
RF signals received by the receive circuitry and to extract the information or data bits conveyed in the received RF signals; and
transmit circuitry configured to receive encoded data from the baseband processor and to modulate a carrier signal with the encoded data, wherein the transmit circuitry is configured to amplify the modulated carrier by way of the MMIC of claim 11.
